(19) United States
(12) Patent Application Publication
(10) Pub. No.: US 2025/0038019 A1
(43) Pub. Date: Jan. 30, 2025

(54) MANUFACTURING SYSTEM AND METHOD OF SEMICONDUCTOR DEVICE

(71) Applicant: HITACHI HIGH-TECH CORPORATION, Minato-ku, Tokyo (JP)

(72) Inventors: Makoto SATAKE, Tokyo (JP); Pushe ZHAO, Tokyo (JP); Takamasa ICHINO, Tokyo (JP); Masahiro MORIZUKI, Tokyo (JP)

(21) Appl. No.: 18/280,600

(22) PCT Filed: Sep. 26, 2022
(86) PCT No.: PCT/JP2022/035648

§ 371 Date: Sep. 6, 2023

(51) Int. Cl. H01L 21/67; H01L 21/66

(52) U.S. Cl. CPC H01L 21/67248; H01L 21/67103; H01L 22/20

(57) ABSTRACT

A semiconductor device manufacturing system and method for improving processing yield including a semiconductor device manufacturing apparatus including a wafer stage having an upper surface configured to allow the wafer to be placed, a plurality of heaters disposed inside the wafer stage and below a plurality of regions of the upper surface, and a controller configured to adjust outputs of a plurality of heater power supplies supplied to the plurality of heaters; and a wafer temperature calculation system configured to determine whether first output values of the plurality of the heater power supplies calculated in advance to implement a target temperature of the wafer during the processing are within an allowable range, and calculate second output values obtained by correcting all the first output values to values within the allowable range when the first output values are out of the allowable range.

### TECHNICAL FIELD

The present invention relates to a wafer temperature method in a semiconductor wafer processing system.

### BACKGROUND ART

With the development of three-dimensional structures of semiconductor devices, there is an increasing demand for a manufacturing technique for manufacturing a complicated device structure uniformly in a wafer plane. In the manufacture of the semiconductor device, processes using a plurality of semiconductor manufacturing apparatuses such as an exposure device, a heat treatment device, a dry etching device, a wet cleaning device, a film forming device, and a chemical mechanical polishing (CMP) device are repeated to form a target pattern on an entire surface of a wafer, thereby manufacturing a chip.

Further, to confirm that the manufactured chip is a non-defective chip satisfying target requests, a specific physical quantity such as a dimension or a film thickness of the pattern including a film of a plurality of layers formed in the surface of the wafer is measured by using semiconductor inspection devices such as a critical dimension scanning electron microscope (CD-SEM), an optical critical dimension (OCD), a scanning transmission electron microscope (STEM), a transmission electron microscope (TEM), an optical film thickness meter, and an ellipsometer. In the measurement using the semiconductor inspection devices, to inspect the number of non-defective chips obtainable from the wafer plane, it is general to measure a plurality of places in the wafer plane instead of measuring only one place.

Further, measurement results such as the dimension, the film thickness, and the like obtained as described above are reflected in conditions for processing the wafer (process conditions) by feeding back or feeding forward to the semiconductor manufacturing apparatuses. An operation of the semiconductor manufacturing apparatus is adjusted to be close to the processing condition capable of obtaining a desired shape of the wafer surface after the processing, thereby increasing the number of non-defective chips obtainable from one wafer plane and improving a yield of the processing. Such semiconductor manufacturing apparatuses are provided with a device control method capable of controlling the feedback or the feedforward control based on measured data to set a distribution of a specific physical quantity in the wafer plane to a desired distribution.

As one of methods for controlling the wafer in-plane distribution of the specific physical quantity such as the pattern dimension or the film thickness to the desired distribution, it has been known in the related art to control a temperature distribution in an in-plane direction of the wafer when the wafer is processed in the semiconductor manufacturing apparatus. As an example of such a technique in the related art, a technique disclosed in JP2006-228816A (PTL 1) is known. PTL 1 discloses a method in which in a post-exposure baking process of promoting a chemical reaction in a resist film after exposing a resist pattern by an exposure device, an in-plane temperature of a heat treatment plate divided into a plurality of regions and performing heating in each of the regions is controlled, and a pattern dimension in an in-plane direction of a wafer held above the heat treatment plate is controlled. PTL 1 also discloses a method in which, in order to form a uniform pattern in a wafer plane, a target temperature distribution in the in-plane direction is calculated based on a relational expression, which is obtained in advance, between a temperature of the heat treatment plate and the pattern dimension such that the pattern dimension in the in-plane direction of the wafer is uniformly formed, and a temperature of each of the regions of the heat treatment plate is set to achieve the temperature distribution.

Further, JP2009-302390A (PTL 2) discloses that in a plasma etching device, which is a dry etching device, a temperature distribution in a wafer plane is calculated based on a temperature of a coolant for cooling a sample stage, power of each of heaters disposed in three circular or ring-shaped regions including a center, a middle, and an edge disposed in a dielectric film covering an upper surface of the sample stage to heat the sample stage, and a temperature of a sensor disposed on the sample stage to measure a temperature of the sample stage. In addition, JP2013-513967A (PTL 3) discloses a technique in which in a plasma etching device, an in-plane temperature distribution in which a uniform pattern in a wafer plane is formed is calculated based on a relational expression, which is obtained in advance, between a wafer temperature and a pattern dimension, and an output of heater power is controlled to achieve a target in-plane temperature distribution.

### CITATION LIST

### Patent Literature

PTL 1: JP2006-228816A
PTL 2: JP2009-302390A
PTL 3: JP2013-513967A

### SUMMARY OF INVENTION

### Technical Problem

In the related arts described above, problems occur since the following points are not sufficiently considered.

That is, in the related arts described above, the target in-plane temperature distribution in which a desired circuit pattern of a semiconductor device is formed in the wafer plane is calculated based on a relational expression, which is obtained in advance, between a temperature of a wafer and a dimension value of a pattern, for example, a critical dimension (CD) value, and the output of the heater power is adjusted to achieve the target in-plane temperature distribution. However, in practice, a temperature calculated as a target or a size of the power to the heater required to implement the target temperature during the processing on the wafer may be a value exceeding a range that can be implemented by a plasma processing device. In this case, it is found that the yield of the processing is impaired, for example, the target temperature cannot be achieved and the formed circuit pattern cannot achieve a desired performance.

In this way, one of reasons why the temperature of the wafer and an output value of the heater required to implement the target temperature of the wafer is calculated to be a value exceeding the range that can be implemented by the device is that an amount of heat required to implement the target temperature of one region in the wafer is physically difficult to be implemented by a heat generation amount of the heater corresponding to the region due to heat transfer in the wafer. That is, the inventors have found that a part of the heat formed from the heater corresponding to one region is transferred to another adjacent or near region, and the heat generation amount of the heater required to bring the temperature of the one region in the wafer to a target value may exceed a maximum value that can be implemented, or conversely, even when the heat generation amount is 0, the temperature of the region may exceed the target value, and the target temperature distribution of the wafer may be impossible to be implemented by adjusting the power supplied to a plurality of heaters corresponding to a plurality of regions and the heat generation amount based on the power.

In this way, the techniques in the related art do not consider a problem that the temperature distribution of the wafer during the processing cannot be set to an initial temperature distribution, and the yield of the processing on the wafer is impaired.

An object of the invention is to provide a semiconductor device manufacturing system and a semiconductor device manufacturing method for improving a yield of processing.

### Solution to Problem

To solve the technical problem, the invention provides a method for correcting a target temperature distribution of a wafer that is difficult to implement to a distribution that can be implemented.

That is, the object described above is achieved by a semiconductor device manufacturing system for processing a wafer, including: a semiconductor device manufacturing apparatus including a wafer stage having an upper surface configured to allow the wafer to be placed, a plurality of heaters disposed inside the wafer stage and below a plurality of regions of the upper surface, and a controller configured to adjust outputs of a plurality of heater power supplies supplied to the plurality of heaters; and a wafer temperature calculation system configured to determine whether first output values of the plurality of the heater power supplies calculated in advance to implement a target temperature of the wafer during the processing are within an allowable range, and calculate second output values obtained by correcting all the first output values to values within the allowable range when the first output values are out of the allowable range.

### Advantageous Effects of Invention

According to the invention, a target temperature distribution capable of forming a desired shape of the wafer in an in-plane direction is calculated by using a correlation, which is obtained in advance, between the wafer temperature and a specific physical quantity, and then an amount of power supplied to the plurality of heaters capable of implementing the target temperature distribution is calculated. Further, it is determined whether the target temperature distribution can be implemented by using a value of the amount of power before the wafer is processed. As a result, when it is determined that a value of an output from a heater power supply cannot be implemented, calculated are a second target temperature distribution in which an objective function can be minimized among outputs of the heater power supplies that can be implemented, and the amount of power supplied to the plurality of heaters capable of implementing the second target temperature distribution.

Accordingly, the target temperature distribution of the wafer during the processing is prevented from not being implemented, and a stop of the wafer processing is reduced. In addition, the temperature of the wafer during the processing is prevented from deviating from a desired temperature, and a yield of the processing is improved.

### BRIEF DESCRIPTION OF DRAWINGS

FIG. 1 is a schematic diagram showing a configuration of a semiconductor device manufacturing system according to an embodiment of the invention.

FIG. 2 is a longitudinal sectional view schematically showing a configuration of a wafer stage provided in a semiconductor device manufacturing apparatus according to the embodiment.

FIGS. 3A and 3B are plan views schematically showing examples of a disposition of heater zones in an upper surface of the wafer stage.

FIGS. 4A and 4B are schematic diagrams showing heater zones determined to be impossible to be implemented in a wafer temperature calculation system shown on a display device connected to the semiconductor device manufacturing apparatus according to the embodiment.

FIG. 5A is a flowchart showing a flow of operations of the wafer temperature calculation system according to the embodiment.

FIG. 5B is a flowchart showing a flow of operations of the wafer temperature calculation system according to the embodiment.

FIG. 6 is a flowchart showing a flow of operations of the wafer temperature calculation system according to the embodiment.

FIG. 7 is a flowchart showing a flow of operations added to the present embodiment shown in FIGS. 5A and 5B.

### DESCRIPTION OF EMBODIMENTS

Hereinafter, an embodiment according to the invention will be described with reference to the drawings.

Hereinafter, the embodiment according to the invention will be described with reference to the drawings. The invention is not limited to the embodiment. Further, in the description of the drawings, the same parts are designated by the same reference numerals. When there are a plurality of components having the same or similar functions, different subscripts may be added to the same reference numeral to perform the description. Further, when there is no need to distinguish the plurality of components, the subscripts may be omitted to perform the description. To facilitate understanding of the invention, a position, a size, a shape, a range, or the like of each component shown in the drawings may not represent an actual position, size, shape, range, or the like. Therefore, the invention is not necessarily limited to the position, the size, the shape, the range, or the like shown in the drawings.

In the present disclosure, a “surface” may refer to not only a surface of a plate-shaped member but also an interface of a layer included in the plate-shaped member and substantially parallel to the surface of the plate-shaped member. Further, an “upper surface” or a “lower surface” means a surface shown on an upper side or a lower side in the drawings when the plate-shaped member or the layer included in the plate-shaped member is shown. The “upper surface” and the “lower surface” may be referred to as a “first surface” and a “second surface”, respectively.

The term “above” means a vertically upward direction when the plate-shaped member or the layer is horizontally placed. A direction against the above is referred to as “below”. In addition, the term “in-plane distribution” refers to a distribution in an in-plane direction. The in-plane distribution is also referred to as an “in-plane direction distribution”.

### Embodiment 1

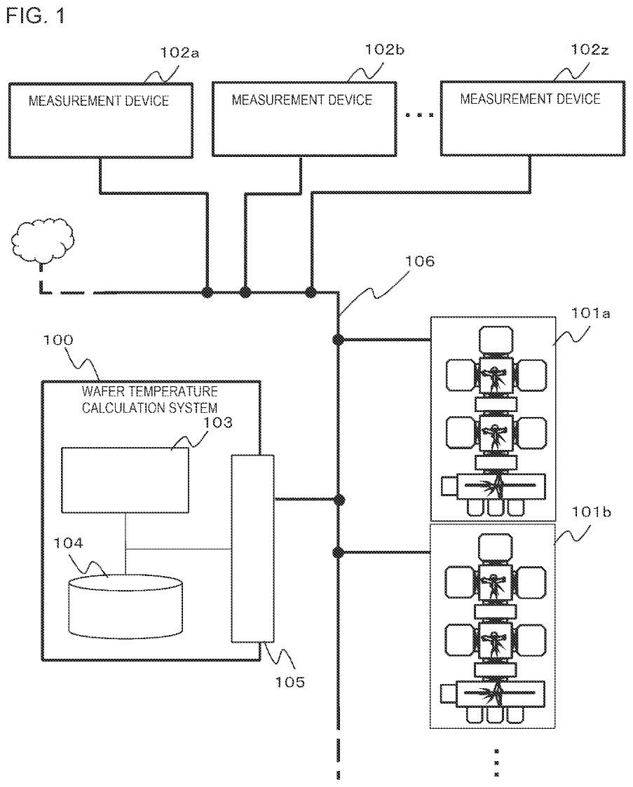

An embodiment according to the invention will be described with reference to FIGS. 1 to 6.

FIG. 1 is a schematic diagram showing a configuration of a semiconductor device manufacturing system according to the embodiment of the invention. The present drawing schematically shows an overall configuration of the semiconductor device manufacturing system, and shows a processing device of a semiconductor wafer, such as an etching processing device, which is a device for implementing a distribution of a specific physical quantity (for example, a shape or a dimension of a circuit pattern formed in a wafer surface) in the in-plane direction of the wafer by processing the semiconductor wafer.

The semiconductor device manufacturing system according to the present example includes a plurality of semiconductor device manufacturing apparatuses 101 (in the drawing, 101a, 101b, and the like are shown) such as etching processing devices, a plurality of wafer measurement devices 102 (102a to 102Z), and a wafer temperature calculation system 100. The semiconductor device manufacturing apparatuses 101 each include, inside a container, a sample stage (wafer stage) having an upper surface on which a wafer is disposed and having a function of variably adjusting a temperature distribution of the wafer in the in-plane direction. The wafer measurement devices 102 are capable of measuring a distribution of a specific physical quantity in a plane of the wafer. The wafer temperature calculation system 100 calculates the temperature distribution in the in-plane direction of the wafer processed by the semiconductor device manufacturing apparatuses 101. Further, the wafer temperature calculation system 100, the plurality of semiconductor device manufacturing apparatuses 101, and the plurality of wafer measurement devices 102 are communicably connected by a wired or wireless communication method to transmit and receive signals to and from one another. To transmit and receive data, it is desirable that the wafer temperature calculation system 100, the semiconductor device manufacturing apparatuses 101, and the wafer measurement devices 102 are connected to a so-called network such as Ethernet and can communicate with one another via the network, and any form capable of transmitting and receiving the data to and from one another may be used. For example, a recording medium such as a flash memory such as a floppy disk, a USB memory, and an SD card, a CD, a DVD, and a Blu-Ray disk (registered trademark) may be used to transmit and receive the data to and from one another.

Further, the wafer temperature calculation system 100 includes an arithmetic unit 103 such as a microprocessor, a storage device 104 holding and storing data related to the wafer and software for driving the arithmetic unit 103 in a readable and writable manner, and an interface 105 that is communicably connected to the network and is used for transmitting and receiving signals including data, which are configured to communicate with one another. The wafer temperature calculation system 100 may have a configuration in which the arithmetic unit 103, the storage device 104, and the interface 105 are incorporated in a so-called computer such as a PC or a server, and the storage device 104 may be disposed at a remote place that is communicably connected. The semiconductor device manufacturing apparatuses 101 and the wafer measurement devices 102 do not need to be disposed inside the same building, and may be communicably disposed in another building or another place.

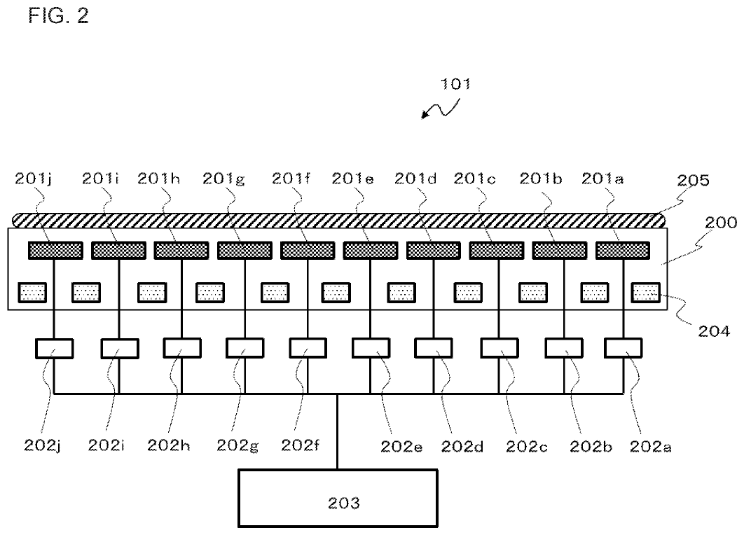

FIG. 2 is a longitudinal sectional view schematically showing a configuration of the wafer stage provided in the semiconductor device manufacturing apparatus according to the embodiment. Each of the semiconductor device manufacturing apparatuses 101 according to the present example includes a wafer stage 200 shown in FIG. 2 in a processing chamber inside the container. The wafer stage 200 has a circular plate shape or a cylindrical shape having a central axis in common with a central axis of the processing chamber having a cylindrical shape, and includes a plurality of heaters 201 (201a to 201j) and a coolant flow path 204. The heaters 201 are disposed inside along an upper surface of a base material made of metal of the wafer stage 200. The coolant flow path 204 is disposed inside the base material below the heaters 201 in a multiple concentric shape or a spiral shape, and allows a coolant for cooling the wafer to flow.

By adjusting heat generation amounts of the plurality of heaters 201 and adjusting a temperature of the coolant flowing through the coolant flow path 204, a temperature distribution of a wafer 205 in the in-plane direction is adjusted in a state where the wafer 205 is placed and held on a dielectric film covering an upper surface of the wafer stage 200. In the wafer stage 200 according to the present example, each of the heaters 201 corresponds to a plurality of zones obtained by dividing the upper surface of the wafer stage 200 on which the wafer 205 is placed in a radial direction or a circumferential direction and is disposed below the zones, and each heater 201 constitutes a plurality of heater zones. Each of heater power supplies 202 (202a to 202j) respectively connected to the heaters 201 electrically receives a command signal from a heater control unit 203 communicably connected to the heater power supplies 202 to adjust values of power (a current or a voltage) output based on the command signal, thereby adjusting a heat generation amount and a temperature of each heater zone and a temperature of a region of the mounted wafer 205 corresponding to the heater zone to values within ranges suitable for processing.

Although not shown in FIG. 2, a temperature sensor that senses a temperature of the base material of the wafer stage 200 may be disposed corresponding to each heater zone and inside the base material below each zone. Further, an output from the temperature sensor may be transmitted to the heater control unit 203, and information on the detected temperature may be fed back or fed forward to adjust an output of the heater power supply 202.

The coolant circulates and flows between the coolant flow path 204 and a coolant temperature controller connected via a pipe line (not shown), and is adjusted to a temperature in a predetermined range in the coolant temperature controller. If necessary, coolants set to different temperatures may be supplied to a plurality of the coolant flow paths 204. Further, the wafer stage 200 may have a configuration in which the coolant flow path 204 is omitted if temperature controllability in the wafer plane is sufficient.

In FIG. 2, the coolant flow path 204 through which the coolant flows is disposed below the heaters 201, and the coolant flow path 204 may be disposed above the heaters. Further, although not shown in FIG. 2, the wafer stage 200 includes a holding mechanism capable of holding the wafer 205 placed on the upper surface of the wafer stage 200 and preventing a positional deviation, such as a mechanical chuck, a vacuum chuck, and an electrostatic chuck.

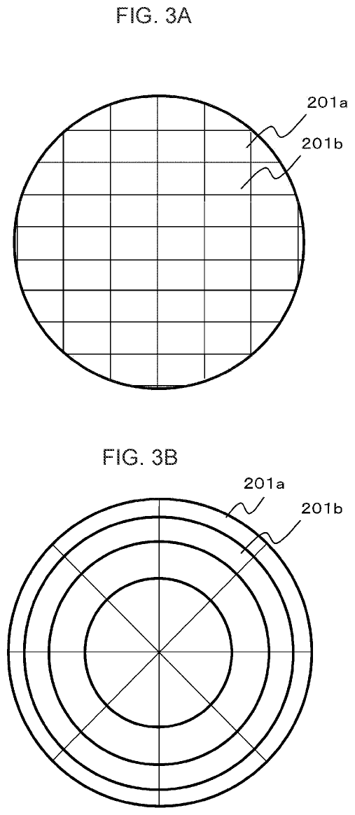

FIGS. 3A and 3B show examples of the heater zones in the upper surface as viewed from above the wafer stage 200. FIGS. 3A and 3B are plan views schematically showing examples of disposition of the heater zones in the upper surface of the wafer stage. FIG. 3A shows an example of a pattern in which the heater zones are divided into a grid shape, and FIG. 3B shows an example of a pattern on a concentric circle.

In the present example, the size, the disposition, and the number of the heater zones are not limited to those shown in FIGS. 3A and 3B as long as a desired temperature distribution of the wafer 205 in the in-plane direction is implemented by appropriately selecting a shape and a position of the heater 201 or the output of the heater power supply 202.

In each of the semiconductor device manufacturing apparatuses 101, a specific correlation is established between values of outputs (the heat generation amounts) of the plurality of heaters 201 or values of the outputs from the heater power supplies 202 and the temperature of the coolant, and the temperature of the wafer 205 placed on the wafer stage 200 in each zone. In the present example, such a correlation is set as a first correlation, and the temperature distribution of the wafer 205 in the in-plane direction can be predicted by using data indicating the first correlation calculated or obtained in advance and setting values of the output of the heater power supply 202 and the temperature of the coolant. Further, when the temperature sensor is disposed in order to sense the temperature of each heater zone, accuracy of the prediction can be improved by including temperature data obtained from the output of the temperature sensor in the first correlation or using the temperature data to predict the temperature of the wafer 205 together with the first correlation.

The first correlation can be expressed using a matrix in associating the plurality of heater zones with the temperatures of places in the plurality of regions of the wafer 205. In addition, the first correlation can also be expressed by using a simultaneous differentiation equation.

An upper limit value and a lower limit value of the outputs of the plurality of heater power supplies 202 provided in each of the semiconductor device manufacturing apparatuses 101 according to the present example, and an upper limit value and a lower limit value of the temperature of the wafer 205 obtained by using the first correlation are determined by the configuration of each of the semiconductor device manufacturing apparatuses 101, and thus are unique to a semiconductor device manufacturing apparatus 101. Further, during the processing on any wafer 205, when the output of the heater power supply 202 or the temperature of the wafer 205 deviates from an allowable range determined by the unique values, the processing on the wafer 205 is stopped to avoid failure or damage to a function of the wafer stage 200. Therefore, when the wafer 205 is processed, the output of the heater power supply 202 and the temperature of the wafer 205 need to be set to values within the allowable range not exceeding the upper or lower limit values.

The wafer 205 processed in each of the semiconductor device manufacturing apparatuses 101 is transferred to one of the plurality of wafer measurement devices 102 (102a to 102z), and the distribution of the specific physical quantity to be detected or evaluated is detected in the in-plane direction of the wafer 205. Further, if necessary, the distribution of the specific physical quantity before the processing in each of the semiconductor device manufacturing apparatuses 101 can be detected by any of the wafer measurement devices 102. However, it is not always necessary to detect the specific physical quantity of the processed wafer 205 immediately after being processed in each of the semiconductor device manufacturing apparatuses 101. The wafer 205 after being processed in each of the semiconductor device manufacturing apparatuses 101 may be transferred to another device to be subjected to at least one processing, and then transferred to the wafer measurement device 102, so that the distribution of the specific physical quantity of the wafer 205 in the in-plane direction can be detected.

Further, a surface of the wafer 205 processed in one semiconductor device manufacturing apparatus 101 can be measured by using the plurality of wafer measurement devices 102. That is, the wafer 205 processed by the semiconductor device manufacturing apparatus 101a can be transferred to the wafer measurement device 102a and subsequently to the wafer measurement device 102b to detect distributions of one or more specific physical quantities in the surface of the wafer 205 therein.

The following will describe an operation of calculating the target temperature distribution of the wafer 205 in the in-plane direction in one of the semiconductor device manufacturing apparatuses 101 by using the wafer temperature calculation system 100, and an operation of correcting, if it is determined that the target temperature distribution cannot be implemented, the target temperature distribution to a target temperature distribution that can be implemented. The following will describe, for example, a case where the semiconductor device manufacturing apparatus 101a is to be subjected to the calculation of the target temperature distribution and the wafer measurement device 102a is used as a device that detects the specific physical quantity, and the same operation can also be performed when another semiconductor device manufacturing apparatus or another wafer measurement device is used in the embodiment according to the invention.

The wafer temperature calculation system 100 has a function of storing the first correlation between the output from each heater power supply 202 in the wafer stage 200 and the temperature in-plane distribution of the wafer 205 and data on a range that can be output by the heater power supply 202 and the allowable range of the temperature of the wafer 205 in each of the semiconductor device manufacturing apparatuses 101a to 101z into each of the semiconductor device manufacturing apparatuses 101 in a readable and writable manner and, as necessary, updating the data. When the data is periodically transmitted and received between the wafer temperature calculation system 100 and the semiconductor device manufacturing apparatus 101a and the same content is stored by the two, and a structure of the wafer stage 200 including the heater 201 and the heater power supply 202 of the wafer stage 200 and the temperature of the coolant are changed, information related to the change is held and stored in the wafer temperature calculation system 100 and is reflected in the operation when the transmission and reception of the data are periodically performed. Accordingly, by using the data shared for any wafer 205, the target temperature distribution can be implemented, and the processing on the wafer 205 can be performed with a high accuracy.

Next, the wafer temperature calculation system 100 has a function of associating a processing recipe for processing the wafer 205 by the semiconductor device manufacturing apparatus 101a with data obtained by measuring the specific physical quantity distribution of the processed wafer 205 in the in-plane direction by the wafer measurement device 102a. Here, the processing recipe includes data on a target temperature in-plane distribution of the wafer 205 set in the wafer stage 200, a temperature distribution detected during the actual processing by using the temperature sensor, or the output value of each heater power supply 202. Accordingly, the temperature distribution of the wafer 205 in the semiconductor device manufacturing apparatus 101 can be associated with the specific physical quantity distribution of the wafer 205 in the in-plane direction measured by the wafer measurement device 102.

The wafer temperature calculation system 100 has a function of, when the specific physical quantity distribution of the wafer 205 in the in-plane direction is detected before the wafer 205 is processed in the semiconductor device manufacturing apparatus 101a, associating the data thereof with the processing recipe of the semiconductor device manufacturing apparatus 101a. With the configuration, the specific physical quantity distributions before and after the processing of the wafer 205 in the in-plane direction in the semiconductor device manufacturing apparatus 101a can be associated with each other, and based on a difference in the in-plane distribution of the wafer before and after the processing, the temperature in-plane distribution of the wafer set in the semiconductor device manufacturing apparatus 101a can be associated with a wafer in-plane distribution of a change amount of the specific physical quantity before and after the processing.

The wafer temperature calculation system 100 has a function of calculating a second correlation between a setting value of the temperature distribution of the wafer 205 in the in-plane direction in the semiconductor device manufacturing apparatus 101a and the specific physical quantity distribution of the wafer 205 in the in-plane direction, and holding and storing the second correlation as data related to the semiconductor device manufacturing apparatus 101a. For example, the second correlation can be calculated, prior to processing the wafer 205 for manufacturing the semiconductor device, by using data obtained by processing two or more wafers 205 by using different temperature distribution settings in the semiconductor device manufacturing apparatus 101a, transferring each wafer 205 to the wafer measurement device 102a, and detecting the specific physical quantity.

That is, the second correlation is calculated by using a result obtained by associating conditions of the different temperature distributions set for the two or more wafers 205 with data on detection results of the specific physical quantity distributions of the wafers 205 in the in-plane direction. As a method of calculating the second correlation, a least squares method using linear or polynomial approximation can be used, and another method may also be used.

Next, the wafer temperature calculation system 100 has a function of calculating, by using the stored second correlation, the target temperature distribution in which an objective function using the specific physical quantity in the wafer stage 200 of the semiconductor device manufacturing apparatus 101a is minimized. Examples of the objective function according to the present embodiment include an objective function obtained by setting target values of the specific physical quantity on a plurality of coordinates of the wafer 205 in the in-plane direction, calculating a value obtained by squaring a difference between the target value at a certain designated coordinate in the surface of the wafer 205 and a predicted value at the designated coordinate calculated based on the second correlation, and adding squaring values at the plurality of designated coordinates.

The target value of the specific physical quantity used when calculating the objective function may not necessarily be set to the same value in the in-plane direction of the wafer 205. As a result of the processing on the wafer 205 in the in-plane direction, for example, different target values may be set for the coordinates to be capable of obtaining a processed shape, and the target values in processes of the processing may be different even at the same coordinate on the wafer 205 depending on types, contents, and conditions of previous and subsequent processing. In this way, in the present embodiment, an appropriate objective function is set, and a temperature distribution of the wafer 205 in the in-plane direction in which the set objective function is minimized. The target temperature distribution of the wafer 205 during the processing is calculated, in which a desired physical quantity distribution is achieved after the processing.

The wafer temperature calculation system 100 has a function of calculating, by using a first correlation in the semiconductor device manufacturing apparatus 101a, a predicted value of the output of the heater power supply 202 connected to each heater zone for implementing the calculated target temperature distribution. In the actual processing on the wafer 205, the output of the heater power supply 202 is set to a value of 0 or more, and the predicted value of the output calculated here may be a negative value that cannot be physically implemented by extrapolating the first correlation. That is, even in a case of the target temperature distribution of the wafer 205 which cannot be actually implemented due to the presence of the heat transfer between the plurality of heater zones through the wafer 205, the output values of the plurality of heater power supplies 202 which can implement the target temperature distribution during the processing are calculated.

Next, the wafer temperature calculation system 100 has a function of determining whether the calculated target temperature distribution of the wafer stage 200 can be implemented based on the upper and lower limit values in the allowable range of the temperature of the wafer 205 being processed and the upper and lower limit values in the range that can be output by the heater power supply 202 in the semiconductor device manufacturing apparatus 101a. That is, in the wafer temperature calculation system 100, a value of the calculated target temperature and the predicted value of the output of the heater power supply 202 are compared with the two sets of upper and lower limit values. Here, when the target temperature of the wafer 205 and the predicted value of the output of the heater power supply 202 during the processing, which are already calculated, do not exceed the respective upper and lower limit values in all the heater zones, the calculated target temperature distribution is recorded in the wafer temperature calculation system 100 as a target temperature distribution that can be implemented.

On the other hand, when it is determined that at least one of the target temperature or the predicted value of the output of the heater power supply 202 exceeds the two upper and lower limit values in one or more heater zones, the calculated target temperature distribution is recorded as a target temperature distribution that cannot be implemented. At this time, the heater zone in which the target temperature or the predicted value of the output of the heater power supply 202 cannot be implemented is specified and recorded by a corresponding code or a corresponding sign, and information thereof can be confirmed when necessary.

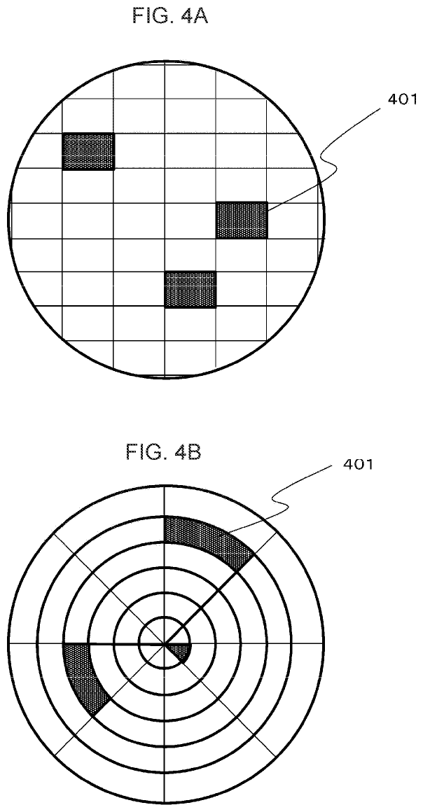

When the heater zone in which the target temperature distribution cannot be implemented is recorded, a name, a sign, or a number can be assigned to each heater zone, and the unimplementable heater zone can be displayed on a display device such as a display communicably connected to the wafer temperature calculation system 100. FIGS. 4A and 4B show a display example.

FIGS. 4A and 4B are schematic diagrams showing heater zones that are determined to be unimplementable in the wafer temperature calculation system and are shown on the display device connected to the semiconductor device manufacturing apparatus according to the embodiment. As shown by a sign 401 in FIG. 4A or FIG. 4B, a graphical user interface (GUI) is used to easily determine where heater zones determined to be unimplementable by the wafer temperature calculation system 100 are located among all the plurality of heater zones in the upper surface of the wafer stage 200 as shaded heater zones 401 on the drawing.

Next, when it is determined that the target temperature distribution cannot be implemented, the wafer temperature calculation system 100 calculates a second target temperature distribution that can be implemented. In the second target temperature distribution, the predicted value of the output of the heater power supply 202 of the heater zone in which the target temperature or the predicted value of the output of the heater power supply 202 is out of the allowable range may be changed alone.

On the other hand, when changing only the predicted value of the output of the heater power supply 202 of the heater 201 corresponding to the heater zone in which the target temperature or the predicted value of the output of the heater power supply 202 is out of the allowable range, a temperature at an unexpected designated coordinate of the wafer 205 may also be changed due to the heat transfer in the wafer 205, the objective function may be large, and on the contrary, the target temperature distribution may be largely deviated from a distribution for obtaining a desired processing result. Therefore, a temperature distribution of the wafer 205 in which the objective function can be minimized among the temperature distributions that can be implemented can be calculated by using the first correlation for predicting the temperature in-plane distribution of the wafer 205 based on the output values of the plurality of heater power supplies 202 and the second correlation between the setting value of the temperature in-plane distribution of the wafer 205 and the specific physical quantity distribution of the wafer 205 in the in-plane direction, and the distribution can be calculated as a second target temperature distribution.

Further, the wafer temperature calculation system 100 reflects one of the target temperature distribution determined to be implementable and the second target temperature distribution in a processing condition (the processing recipe) in the semiconductor device manufacturing apparatus 101a, and transmits the processing recipe to the semiconductor device manufacturing apparatus 101a. After the wafer temperature calculation system 100 performs the calculation, the semiconductor device manufacturing apparatus 101a can process the target wafer 205 by using the transmitted processing recipe including information on the target temperature distribution that can be implemented.

In this way, by using the semiconductor device manufacturing system including the wafer temperature calculation system 100 according to the present embodiment, even when an initial target temperature distribution calculated for obtaining the desired processing result cannot be implemented, the second target temperature distribution in which the objective function can be minimized among the temperature distributions that can be implemented is calculated, the semiconductor device is manufactured based on the second target temperature distribution, and a decrease in a manufacturing yield is prevented.

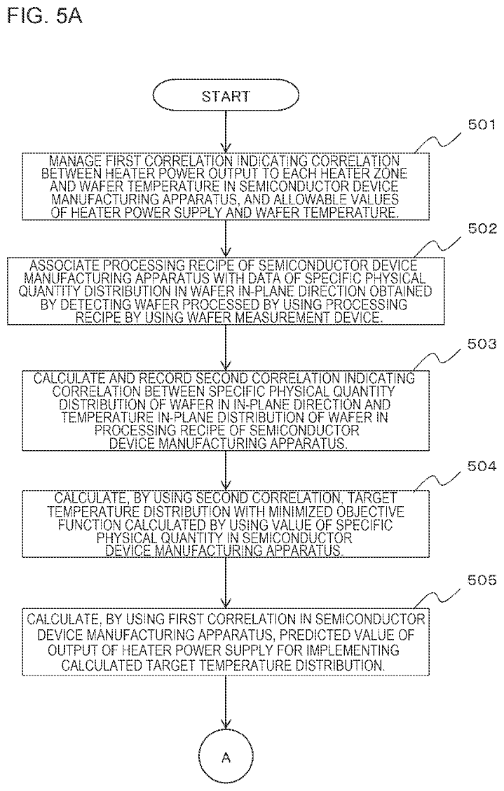

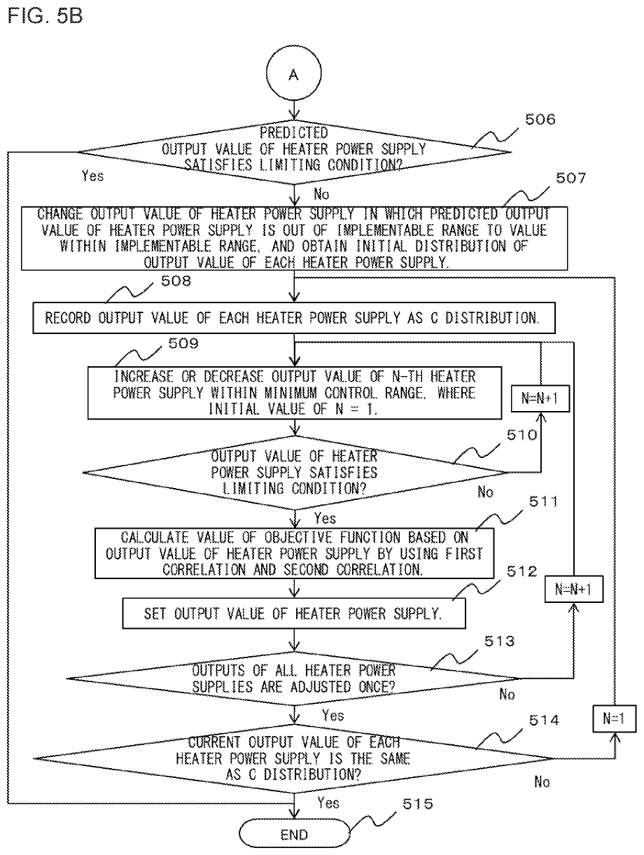

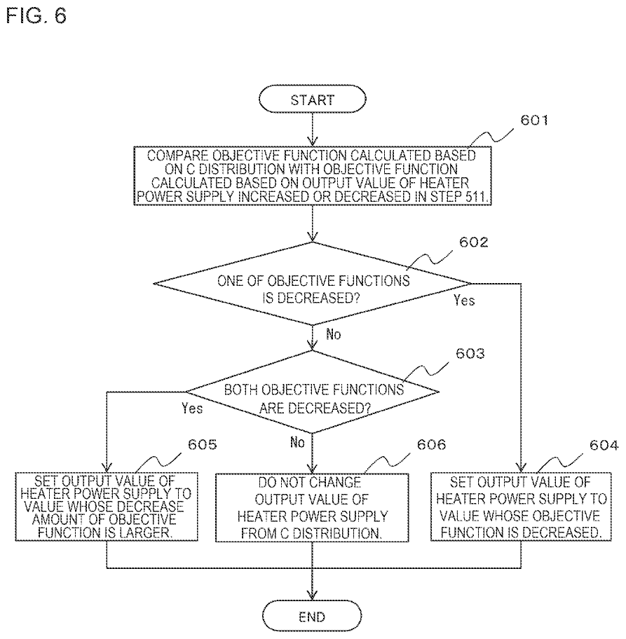

Next, operations of calculating the target temperature distribution in the wafer temperature calculation system 100 according to the embodiment of FIG. 1 will be described with reference to FIGS. 5A to 6. FIGS. 5A to 6 are flowcharts showing flows of operations of the wafer temperature calculation system according to the embodiment. The present example discloses an example in which the semiconductor device manufacturing apparatus 101a and the wafer measurement device 102a are used, and another semiconductor device manufacturing apparatus or another wafer measurement device may be used to perform the same operation and obtain the same effect.

FIGS. 5A and 5B show a flow of a series of operations of calculating a setting value of the target temperature distribution by the wafer temperature calculation system 100. FIG. 6 shows a flow of the operation of setting the output value of the heater power supply 202 in step 512 shown in FIG. 5B in more detail. As shown in step 501, the wafer temperature calculation system 100 according to the present embodiment has a function of managing, for the wafer stage 200 of each of the semiconductor device manufacturing apparatuses 101 connected to the semiconductor device manufacturing system via a communication method such as the network, the first correlation indicating the correlation between the output value of each of the plurality of heater power supplies 202 and the temperature distribution of the wafer 205 in the in-plane direction based on the temperature of the coolant flowing through the coolant flow path 204, and the output value of the heater power supply 202 and the temperature value of the wafer 205 in the allowable range (an allowable amount) in association with each of the semiconductor device manufacturing apparatuses 101a to 101z. The pieces of data are periodically synchronized between the wafer temperature calculation system 100 and each semiconductor device manufacturing apparatus, for example, the semiconductor device manufacturing apparatus 101a, and the same data is stored in and shared by both the wafer temperature calculation system 100 and the semiconductor device manufacturing apparatus 101a. When configurations such as the structure of the wafer stage 200 and a setting temperature of the coolant are changed, data and information reflecting the change are also periodically transmitted to and stored in the wafer temperature calculation system 100.

Next, in step 502, in the semiconductor device manufacturing apparatus 101a, the processing recipe for processing the wafer 205 is associated with data, obtained by processing the wafer by using the processing recipe, on the specific physical quantity distribution of the processed wafer 205 in the in-plane direction, which is detected by the wafer measurement device 102a. Here, the processing recipe also includes data indicating the in-plane direction distribution of the temperature of the wafer 205 during the processing set in the wafer stage 200 or the output value of each heater power supply 202. Accordingly, the in-plane direction distribution of the temperature of the wafer 205 set by the semiconductor device manufacturing apparatus 101 is associated with the in-plane direction distribution of the specific physical quantity of the wafer 205 detected by the wafer measurement device 102.

The wafer temperature calculation system 100 has a function of associating, when the specific physical quantity distribution of the wafer 205 in the in-plane direction is detected in the wafer measurement device 102a before the processing is performed in the semiconductor device manufacturing apparatus 101a, the data on the specific physical quantity distribution of the wafer 205 in the in-plane direction with the processing recipe of the semiconductor device manufacturing apparatus 101a. With the configuration, the specific physical quantity distributions of the wafer 205 in the in-plane direction before and after the processing in the semiconductor device manufacturing apparatus 101a can be associated, and the temperature distribution of the wafer 205 in the in-plane direction set in the semiconductor device manufacturing apparatus 101a can be associated with a distribution of a change amount of the specific physical quantity in the in-plane direction before and after the processing based on a distribution of a difference of the specific physical quantity in the in-plane direction before and after the processing.

Here, a number is assigned to each heater power supply 202 from N=1 to the number of heater power supplies, and the heater zone to which the heater power supply is connected can be determined based on the number. A name of the heater power supply may be any name as long as the heater power supplies can be distinguished from one another, and in the present embodiment, positive integers of N=1 or more are assigned.

Next, in step 503, the wafer temperature calculation system 100 has a function of calculating the second correlation for predicting the specific physical quantity distribution of the wafer 205 in the in-plane direction based on the setting value of the temperature distribution of the wafer 205 in the in-plane direction in the semiconductor device manufacturing apparatus 101a, and has a function of recording and storing the second correlation as data related to the semiconductor device manufacturing apparatus 101a in the internal storage device 104 in association with the semiconductor device manufacturing apparatus 101a. The second correlation is calculated by previously processing the two or more wafers 205 by using the semiconductor device manufacturing apparatus 101a under the conditions of the different temperature distributions in the in-plane direction, and then using a result obtained by associating the data on the distribution in the in-plane direction of a value when the specific physical quantity is detected by the wafer measurement device 102a for each wafer 205.

That is, the second correlation is calculated by using the condition of the temperature distribution of the two or more types of wafers 205 in the in-plane direction and the detection result of the specific physical quantity distribution in the in-plane direction. The second correlation may be calculated by the least squares method using the linear or polynomial approximation, and another method may be used.

Next, in step 504, the wafer temperature calculation system 100 has a function of calculating, by using the recorded second correlation, the target temperature distribution in which the objective function calculated based on the specific physical quantity in the semiconductor device manufacturing apparatus 101a is minimized. The objective function may be set to the objective function obtained by setting the target values of the specific physical quantity on the plurality of coordinates of the wafer 205 in the plane thereof, calculating the value obtained by squaring the difference between the target value at a certain designated coordinate in the plane and the predicted value at the designated coordinate calculated based on the second correlation, and adding the squaring values at the plurality of designated coordinates.

The target value of the specific physical quantity used when calculating the objective function does not necessarily need to be set to the same target value in the wafer plane, and may be any value as long as the value of the specific physical quantity and the distribution thereof by which the desired processing result can be finally obtained in the wafer plane are implemented, and the value of the target value may be changed for each coordinate according to the previous and subsequent processing. In this way, by setting an appropriate objective function and calculating the temperature distribution of the wafer 205 in which the objective function is minimized, the target temperature distribution is calculated in which a desired value of the physical quantity of the wafer 205 in the in-plane direction and the distribution thereof can be finally achieved.

Next, in step 505, the wafer temperature calculation system 100 calculates, by using the first correlation in the semiconductor device manufacturing apparatus 101a, the predicted value of the output of the plurality of the heater power supplies 202 connected to each heater zone for calculating the target temperature distribution. In the actual processing on the wafer 205, the output of the heater power supply 202 is set to a value of 0 or more, and the predicted value of the output calculated here may be a negative value that cannot be implemented by extrapolating the first correlation. Accordingly, even in a case of the target temperature distribution including a value that cannot be actually implemented by the heat transfer in the wafer 205, a set of the output values of the heater power supplies 202 corresponding to the target temperature distribution in terms of calculation is obtained.

Next, in step 506, the wafer temperature calculation system determines whether the predicted output value of the heater power supply satisfies a limiting condition. That is, it is determined whether the target temperature distribution calculated in step 504 can be implemented based on a result of the comparison with the upper and lower limit values in the allowable ranges of the temperature of the wafer 205 and the output of the heater power supply in the semiconductor device manufacturing apparatus 101a. Here, if the target temperature and the predicted value of the output of the heater power supply 202 are within the allowable ranges in all the heater zones, the processing proceeds to an END step, the calculated temperature distribution is reflected in the processing recipe in the semiconductor device manufacturing apparatus 101a as the target temperature distribution that can be implemented and is included therein as data, and the recipe is transmitted to the semiconductor device manufacturing apparatus 101a via a network 106. Further, the semiconductor device manufacturing apparatus 101a can process the wafer 205 by using the processing recipe transmitted from the wafer temperature calculation system 100.

On the other hand, when it is determined that at least one of the target temperature or the predicted value of the output of the heater power supply 202 is out of the allowable range in one heater zone, the target temperature distribution calculated in step 504 is recorded in the storage device 104 as the target temperature distribution that cannot be implemented, and the processing proceeds to step 507. At this time, the heater zone in which it is determined that the target temperature or the predicted value of the output of the heater power supply 202 cannot be implemented is recorded in the storage device 104, and the information on the heater zone can be confirmed when necessary.

Next, in step 507, only the output value of the heater power supply 202 corresponding to the heater zone in which the predicted value of the output is out of the allowable range is changed to fall within the allowable range. That is, the output value of the heater power supply in which the predicted output value of the heater power supply is out of an implementable range is changed to a value within the implementable range. Further, a distribution of all the heater power supplies 202 is recorded as an initial distribution. In step 507, the initial distribution capable of implementing the outputs of all the heater power supplies can be obtained.

Next, in step 508, the output values of all the heater power supplies 202 in a current state are recorded as a C distribution. The C distribution is appropriately updated according to the flow shown in the drawing, and the output of the heater power supply 202 calculated in step 507 is recorded as the initial distribution.

Next, in step 509, an output value of an N-th heater power supply is increased or decreased within a minimum control range. That is, the output value of each heater power supply 202 to which the positive integer is assigned in step 502 is sequentially increased or decreased by a value having a predetermined size. The size of the value for changing can be freely selected in the semiconductor device manufacturing system or the semiconductor device manufacturing apparatus 101a, and needs to be set to a value larger than a minimum width by which the output of the heater power supply 202 can be changed. Further, according to the configuration of the heater power supply 202, the output value of the heater power supply 20′2 used for the same wafer stage 200 can be changed for each heater power supply. For example, when the output value of any heater power supply 202 in the C distribution recorded in step 508 is 50 W and the minimum control range of the heater power supply 202 is 0.1 W, the output value of the heater power supply 202 increased or decreased with a minimum variable width is 50.1 W or 49.9 W.

Next, in step 510, it is determined whether the output value of the heater power supply satisfies a limiting condition. That is, it is determined whether the output of the heater power supply 202 or the temperature of the wafer is within the allowable range by the output value of the heater power supply 202 increased or decreased in step 509. If it is determined that a condition of the allowable range is satisfied, a set of output values including the output value of the heater power supply 202 increased and decreased in step 509 is set as an output value distribution that can be implemented, and the processing proceeds to step 511. On the other hand, if it is determined that the output of the heater power supply 202 or the temperature of the wafer is out of the allowable range, the positive integer N assigned to each heater power supply 202 is increased to N+1 as an output distribution (a set of output values) of the heater power supply 202 which cannot be implemented, the processing returns to step 509, and then an examination is performed on a different heater power supply 202.

Next, in step 511, by using the first correlation between the output value of each heater power supply 202 and the in-plane direction distribution of the temperature of the wafer 205 and the second correlation between the setting value of the in-plane direction distribution of the temperature of the wafer 205 and the in-plane direction distribution of the specific physical quantity of the wafer 205, a value of the objective function is calculated by using the predicted values of the outputs of all the heater power supplies 202 output in step 510.

Next, in step 512, the output value of the heater power supply 202 is updated and set based on the value of the objective function calculated in step 511. The objective function is calculated by using the C distribution obtained in step 508 and is compared with the value of the objective function calculated based on the output value of the heater power supply 202 increased or decreased in steps 509 to 511, and a distribution (a combination) of the output values of the heater power supplies 202 is selected according to a result thereof. A detailed flow of an operation of the process will be described later with reference to FIG. 6.

Next, in step 513, a value of the positive integer N assigned to each heater power supply 202 is confirmed, and if the value of N is the same as the number of the heater power supplies 202 being used and is a largest value, it is determined that all the heater power supplies are changed (at least once adjusted), and the processing proceeds to step 514. Further, if it is determined that the value of N is smaller than the number of the heater power supplies 202 being used, the value of N is increased by one, and the processing returns to step 509.

Next, in step 514, to determine whether the calculation of the objective function and the output distribution of the heater power supply 202 is converged, it is determined whether a distribution of the output value of each heater power supply 202 (that is, the output value of each heater power supply in the current state) set in step 512 is the same as the C distribution. If the distribution is different from the C distribution, the calculation is not converged, the value of N is returned to 1, and the processing returns to a flow of 508. On the other hand, if it is determined that the distribution is the same value as the C distribution, it is determined that the calculation is converged and the second target temperature distribution is calculated, and the processing proceeds to step 515.

In step 515, by using the target temperature distribution calculated in step 506 or step 514 as the target temperature distribution that can be implemented, the calculated target temperature distribution is reflected in the processing recipe in the semiconductor device manufacturing apparatus 101a, the data on the temperature distribution is included in the processing recipe, and the recipe is transmitted to the semiconductor device manufacturing apparatus 101a. Further, the semiconductor device manufacturing apparatus 101a can process the wafer 205 by using the transmitted processing recipe calculated by the wafer temperature calculation system 100.

As described above, according to the operations of the wafer temperature calculation system 100 shown in FIGS. 5A and 5B, it is determined whether the target temperature distribution in which a predetermined objective function is minimized can be implemented, and even when it is determined that the target temperature distribution cannot be implemented, the second target temperature distribution in which the objective function can be minimized among the temperature distributions that can be implemented is calculated, and the processing on the wafer 205 is performed based on the processing recipe in which the second target temperature distribution is reflected. Accordingly, in the processing, the specific physical quantity distribution in the in-plane direction in which the desired processing result is obtained is implemented, and the yield of the processing on wafer 205 is improved.

In FIG. 6, the flow of the operations of step 512 shown in FIG. 5B will be described in more detail. First, in step 601, the value of the objective function calculated in step 511 is compared with the value of the objective function calculated by using a value of the C distribution in step 508. As a result of the comparison, if it is determined in step 602 that only one of the values of the objective functions is decreased, the processing proceeds to step 604, and the output value distribution of the heater power supply 202 in which the value of the objective function is decreased is determined as an output value distribution (set) of the heater power supply 202 to be set. In other words, the output value of the heater power supply is set to a value in which the objective function is decreased. When the value of the objective function calculated in step 511 is decreased, the output value distribution of the heater power supply 202 corresponding to the objective function is updated as a new distribution.

Further, if it is not determined in step 602 that only the value of one of the objective functions is decreased, the processing proceeds to step 603, the value of the objective function calculated based on the C distribution is compared with the value of the objective function calculated in step 511, and it is determined whether the values of both objective functions are decreased. If it is determined that the values of both objective functions are decreased, the processing proceeds to step 605, and it is determined that the output value distribution of the heater power supply 202 corresponding to the output value distribution having a larger decrease amount of the value of the objective function is the output value distribution (set) of the heater power supply 202 to be set. In other words, the output value of the heater power supply is set to have a large decrease amount of the objective function. When the value of the objective function calculated in step 511 is further decreased, the output value distribution of the heater power supply 202 corresponding to the objective function is updated as a new distribution.

On the other hand, if it is not determined in step 603 that the values of both objective functions are decreased, it is assumed that the values of both objective functions are increased or not changed. In this case, the processing proceeds to step 606, and the output value distribution of the heater power supply 202 is not changed from the C distribution. By updating the output value distribution of the heater power supply 202 based on the determination described above, as a result of increasing or decreasing the output of the heater power supply 202 from the C distribution, the output value distribution is changed from the C distribution to the output value distribution of the heater power supply that can reduce the value of the objective function.

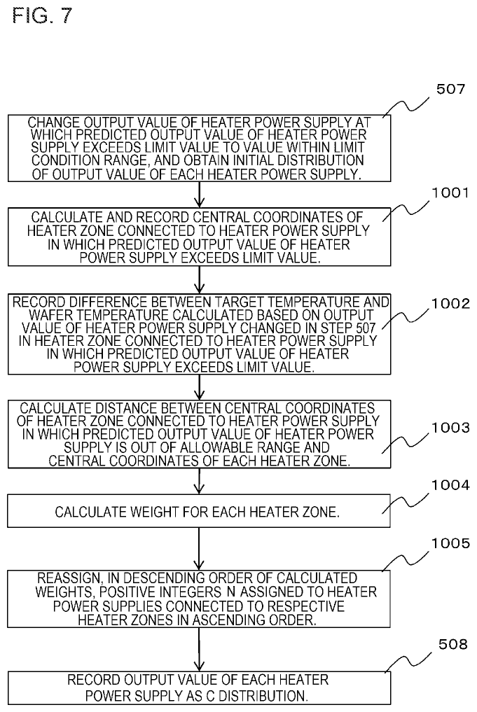

In the embodiment described above, a process of reassigning the positive integer N assigned to each heater power supply 202 if it is determined in step 506 that the output value of the heater power supply 202 is out of the allowable range to shorten a calculation time will be described with reference to FIG. 7. FIG. 7 is a flowchart showing a flow of operations added to the present embodiment shown in FIGS. 5A and 5B. FIG. 7 shows the process performed between step 507 and step 508 in FIG. 5B.

In step 507, only the output value of the heater power supply 202 in which the predicted value of the output is out of the allowable range among the plurality of heater power supplies 202 is changed to fall within the allowable range. Further, the distribution of all the heater power supplies 202 is recorded as the initial distribution. In step 507, it is assumed that the outputs of all the heater power supplies 202 in the current state are the initial distribution that can be implemented.

Next, in step 1001, the wafer temperature calculation system 100 calculates and stores coordinates of a center of the heater zone connected to the heater power supply 202 in which the predicted value of the output of the heater power supply 202 is out of the allowable range. In other words, central coordinates of the heater zone connected to the heater power supply in which the predicted output value of the heater power supply exceeds a limit value are calculated and recorded. Next, the processing proceeds to step 1002, and the wafer temperature calculation system 100 calculates and stores a difference between the target temperature and the temperature of the wafer 205 calculated based on the output value of the heater power supply 202 changed in step 507 in the heater zone connected to the heater power supply 202 in which the predicted value of the output of the heater power supply 202 is out of the allowable range. In other words, in the heater zone connected to the heater power supply in which the predicted output value of the heater power supply exceeds the limit value, the difference between the target temperature and the wafer temperature calculated based on the output value of the heater power supply changed in 507 is recorded. The difference in temperature is calculated by, for example, the following (Formula 1), and is not limited to (Formula 1) as long as the difference in temperature of the wafer 205 calculated based on the target temperature and the output value of the heater power supply is an index.

$$\begin{matrix}[ Equation 1 ] & \\ {E}_{e} = {( T {t}_{e} - T {p}_{e} )}^{2} & ( 1 )\end{matrix}$$

Here, e is a positive integer assigned to the heater zone connected to the heater power supply in which the predicted output of the heater power supply exceeds the limit value, Eₑ is a difference in wafer temperature in the heater zone e, Ttₑ is a target temperature in the heater zone e, and Tpₑ is a wafer temperature calculated based on the output value of the heater power supply changed in 507 in the heater zone e.

Next, in step 1003, calculated is a distance Dᵢₑ between the coordinates of the center of the zone connected to the heater power supply 202 in which the predicted value of the output of the heater power supply 202 is out of the allowable range and coordinates of a center of another heater zone. In other words, calculated is the distance between the central coordinates of the heater zone connected to the heater power supply in which the predicted output value of the heater power supply exceeds the limit value and the central coordinates of each heater zone. Here, i is a positive integer assigned to each heater zone, and e is a positive integer assigned to a heater zone connected to the heater power supply 202 in which the predicted value of the output of the heater power supply is out of the allowable range.

Next, in step 1004, the wafer temperature calculation system 100 calculates a weight for each heater zone. The weight for each heater zone is calculated by, for example, the following equations.

$$\begin{matrix}[ Equation 2 ] & \\ {E}_{s u m} = {\sum }_{e = 1}^{{N}_{e}} ( {E}_{e} ) & ( 2 )\end{matrix}$$

$$\begin{matrix}[ Equation 3 ] & \\ {W}_{i} = {\sum }_{e = 1}^{{N}_{e}} ( {E}_{e} \div {E}_{s u m} ) \times ( \frac{1}{{D}_{ie}} ) & ( 3 )\end{matrix}$$

In the equations, Nₑ is the number of heater zones connected to the heater power supply in which the predicted output of the heater power supply exceeds the limit value, and the weight for each heater zone i can be calculated by (Formula 3).

In the next flow 1005, the larger the weight calculated by (Formula 3) is, the smaller the positive integer N assigned to the heater power supply connected to each heater zone is assigned again.

Next, in step 508, the wafer temperature calculation system 100 records the output value of each heater power supply 202 connected to each heater zone as the C distribution by using the positive integer N reassigned to the heater power supply 202 in 1005.

According to the operations described above, the heater power supply 202 having a larger difference between the target temperature and the predicted temperature is assigned a smaller value of the positive integer N, and the predicted value of the output is preferentially calculated from the heater power supply 202 having a smaller integer N. Therefore, the calculation time of the objective function value or the output value distribution is shortened. Although the present example describes an example in which the central coordinates are used, the coordinates are not limited thereto as long as the coordinates are in the heater zone. For example, coordinates immediately above a place where an input terminal of the heater power supply 202 is connected may be used for the calculation.

According to the embodiment, in the semiconductor device manufacturing apparatus that adjusts the temperature and the distribution of the wafer 205 placed on the wafer stage 200 by using the plurality of heaters 201 inside the wafer stage 200, a first target temperature distribution in which the value of the objective function related to the specific physical quantity distribution after the processing is minimized is calculated in advance before the processing on the wafer 205. Further, the output values of the heater power supplies 202 connected to the plurality of heaters 201 for implementing the target temperature distribution are calculated, and it is determined whether the calculated output values of all the heater power supplies 202 are within the allowable range. When it is determined that the output value of at least one heater power supply 202 among the plurality of the heater power supplies 202 is out of the allowable range and cannot be implemented, the second target temperature distribution that can be implemented and in which the objective function value can be minimized is calculated by using the plurality of the heater power supplies 202, the temperature of the wafer stage 200 and the setting value of the distribution thereof are updated instead of the first target temperature distribution, the temperature distribution of the wafer 205 during the processing in which the desired processing result is obtained is implemented, and the yield of the processing is improved.

The invention is not limited to the embodiment described above, and includes various modifications. For example, the embodiment described above has been described in detail for easy understanding of the invention, and is not necessarily limited to those including all the configurations described above. A part of a configuration of one embodiment can be replaced with a configuration of another embodiment, and the configuration of another embodiment can be added to the configuration of the one embodiment. Further, a part of a configuration of each embodiment can be added to, deleted from, or replaced with another configuration.

### REFERENCE SIGNS LIST

100: wafer temperature calculation system
101: semiconductor device manufacturing apparatus
102: wafer measurement device
200: wafer stage
201: heater
202: heater power supply
203: heater control unit
204: coolant flow path
401: heater zone

1. A semiconductor device manufacturing system for processing a wafer, comprising:
a semiconductor device manufacturing apparatus including a wafer stage having an upper surface configured to allow the wafer to be placed, a plurality of heaters disposed inside the wafer stage and below a plurality of regions of the upper surface, and a controller configured to adjust outputs of a plurality of heater power supplies supplied to the plurality of heaters; and
a wafer temperature calculation system configured to determine whether first output values of the plurality of the heater power supplies calculated in advance to implement a target temperature of the wafer during the processing are within an allowable range, and calculate second output values obtained by correcting all the first output values to values within the allowable range when the first output values are out of the allowable range.

2. The semiconductor device manufacturing system according to claim 1, wherein
the wafer is processed in the semiconductor device manufacturing apparatus by using a processing recipe calculated by setting a first temperature distribution of the wafer corresponding to the first output values or a second temperature distribution calculated based on the second output values as a target temperature distribution during the processing.

3. The semiconductor device manufacturing system according to claim 1, wherein
when it is determined that output values of at least one or more heater power supplies among the plurality of the heater power supplies are out of the allowable range, the controller adjusts the outputs of the plurality of heater power supplies by setting, as a target temperature distribution, a second target temperature distribution calculated based on the second output values at which the output values of the at least one or more heater power supplies are within the allowable range.

4. The semiconductor device manufacturing system according to claim 3, wherein
when it is determined that output values of at least one or more heater power supplies among the plurality of the heater power supplies are out of the allowable range, the wafer temperature calculation system calculates the second target temperature distribution such that the output values of the at least one or more heater power supplies are within the allowable range and a value of a predetermined objective function can be minimized.

5. The semiconductor device manufacturing system according to claim 4, wherein
the wafer temperature calculation system calculates the second target temperature distribution by sequentially increasing or decreasing the output of each of the plurality of heater power supplies until the value of the objective function is minimum.

6. The semiconductor device manufacturing system according to claim 1, wherein
the wafer temperature calculation system and the semiconductor device manufacturing apparatus are communicably connected, and
a first correlation between output values of the plurality of heater power supplies and a temperature distribution of the wafer, an upper limit value and a lower limit value of the allowable range of the output of the heater power supply, and an upper limit value and a lower limit value of a temperature of the wafer in an allowable range calculated based on the first correlation are associated with the semiconductor device manufacturing apparatus and stored in the wafer temperature calculation system.

7. The semiconductor device manufacturing system according to claim 1, wherein
when it is determined that output values of at least one or more heater power supplies among the plurality of the heater power supplies are out of the allowable range, the wafer temperature calculation system stores a region of the heater corresponding to the at least one or more heater power supplies, and includes a display device configured to display the region of the heater.

8. A semiconductor device manufacturing method of processing a wafer by using a semiconductor device manufacturing apparatus including a wafer stage having an upper surface on which the wafer is placed, a plurality of heaters disposed inside the wafer stage and below a plurality of regions of the upper surface, and a controller configured to adjust outputs of a plurality of heater power supplies supplied to the plurality of heaters, the semiconductor device manufacturing method comprising:
determining whether first output values of the plurality of the heater power supplies calculated in advance to implement a target temperature of the wafer during the processing are within an allowable range; and adjusting, when the first output values are out of the allowable range, the heater power supply by the controller to have second output values calculated by correcting all the first output values to values within the allowable range.

9. The semiconductor device manufacturing method according to claim 8, wherein
the wafer is processed in the semiconductor device manufacturing apparatus by using a processing recipe calculated by setting a first temperature distribution of the wafer corresponding to the first output values or a second temperature distribution calculated based on the second output values as a target temperature distribution during the processing.

10. The semiconductor device manufacturing method according to claim 8, wherein
when it is determined that output values of at least one or more heater power supplies among the plurality of heater power supplies are out of the allowable range, the controller adjusts the outputs of the plurality of heater power supplies by setting, as a target temperature distribution, a second target temperature distribution calculated based on the second output values at which the output values of the at least one or more heater power supplies are within the allowable range.

11. The semiconductor device manufacturing method according to claim 10, wherein
when it is determined that the output values of the at least one or more heater power supplies among the plurality of the heater power supplies are out of the allowable range, the wafer temperature calculation system calculates the second target temperature distribution in which the output values of the at least one or more heater power supplies are within the allowable range and a value of a predetermined objective function is capable of being minimized.

12. The semiconductor device manufacturing method according to claim 10, wherein
the second target temperature distribution is calculated by sequentially increasing or decreasing the output of each of the plurality of heater power supplies until the value of the objective function is minimum.

13. The semiconductor device manufacturing method according to claim 8, wherein
the second target temperature distribution is calculated by using a first correlation between output values of the plurality of heater power supplies and a temperature distribution of the wafer, an upper limit value and a lower limit value of the allowable range of the output of the heater power supply, or an upper limit value and a lower limit value of an allowable range of a temperature of the wafer calculated based on the first correlation, which are stored in association with the semiconductor device manufacturing apparatus.

14. The semiconductor device manufacturing method according to claim 8, wherein
when it is determined that output values of at least one or more heater power supplies among the plurality of the heater power supplies are out of the allowable range, a region of the heater corresponding to the at least one or more heater power supplies is stored, and the region of the heater is displayed.
